(19) United States
(12) Patent Application Publication
(10) Pub. No.: US 2023/0241636 A1
(43) Pub. Date: Aug. 3, 2023

(54) SUBSTRATE PROCESSING APPARATUS AND SUBSTRATE PROCESSING METHOD

(71) Applicant: SHIBAURA MECHATRONICS CORPORATION, Kanagawa (JP)

(72) Inventor: Yoko TAKAKITA, Kanagawa (JP)

(21) Appl. No.: 18/103,462

(22) Filed: Jan. 30, 2023

(30) Foreign Application Priority Data
Feb. 1, 2022 (JP) 2022-014140
Dec. 26, 2022 (JP) 2022-208238

(51) Int. Cl. B05B 12/18; B05B 9/00; B05B 16/40

(52) U.S. Cl. CPC B05B 12/18; B05B 9/002; B05B 16/40

(57) ABSTRACT

The substrate processing apparatus includes: a rotating unit that holds and rotates a substrate; a processing liquid supply unit including an ejecting unit that supplies a processing liquid from the ejecting unit to a target surface of the substrate that is being rotated by the rotating unit so as to process the substrate; and the receiving unit 30 including a container having an open top, and relatively movable with respect to the ejecting unit 21 between a block position where the supply of the processing liquid from the ejecting unit 21 is blocked and an allowance position where the supply of the processing liquid from the ejecting unit is allowed.

### CROSS-REFERENCE TO RELATED APPLICATIONS

This application is based on and claims priority from Japanese Patent Application Nos. 2022-014140 and 2022-208238, filed on Feb. 1, 2022, and Dec. 26, 2022, respectively, with the Japan Patent Office, the disclosures of which are incorporated herein in their entireties by reference.

### TECHNICAL FIELD

The present disclosure relates to a substrate processing apparatus and a substrate processing method.

### BACKGROUND

In a manufacturing process for manufacturing, for example, a semiconductor or a liquid crystal panel, a substrate processing apparatus that supplies a processing liquid to a target surface of a substrate such as a semiconductor wafer or a liquid crystal substrate to process the target surface has been used.

For example, a single-wafer type etching device has been used in which the substrate is processed one by one by supplying a processing liquid for etching to the vicinity of the rotation center of the substrate while rotating the substrate held on a rotation table in a chamber so as to spread the processing liquid over the surface of the substrate. Further, after the etching processing, a cleaning device that cleans the substrate in another chamber by supplying the processing liquid for cleaning to the vicinity of the rotation center of the substrate while rotating the substrate held on a rotation table, has been used.

In this substrate processing apparatus, for example, a swing arm provided with a nozzle that ejects the processing liquid at the tip thereof is provided as a mechanism that supplies the processing liquid onto the substrate. The swing arm is provided to be swingable between a standby position where the nozzle is deviated from an upper side of the substrate and an ejection position where the nozzle is positioned at an upper side of the center of the substrate processing the substrate by supplying the processing liquid to the rotating substrate at the ejection position.

Here, in order to obtain a desired processing rate, the processing liquid supplied to the substrate may be adjusted to an appropriate flow rate and temperature. For this reason, the flow rate and temperature of the processing liquid are adjusted first in a state where the processing liquid is ejected in advance from the nozzle that supplies the processing liquid, and then, the processing liquid is supplied to the substrate. As described above, the state where the processing liquid is ejected in advance before the main ejection in which the processing liquid is ejected to the substrate to become a product is referred to as a dummy ejection.

### SUMMARY

When a substrate does not exist at the location where the processing liquid is dropped in a dummy ejection, the processing liquid may be scattered around the rotation table, which causes particles. For this reason, during the dummy ejection, a substrate that will not become a product (e.g., a dummy substrate) may be placed on the rotation table. Since the dummy substrate is necessary when performing the dummy ejection, an operation to carry in/out the dummy substrate is required before and after the ejection of the processing liquid, and thus, the processing time is prolonged, and the throughput is reduced.

Further, after adjusting the flow rate and temperature of the processing liquid during the dummy ejection, the temperature of the processing liquid in the pipe that supplies the processing liquid to the nozzle is lowered until the dummy substrate is carried out and the main substrate which becomes a product is carried in to start the main ejection. Then, when the processing liquid is supplied for the main ejection, the processing liquid is ejected at a lower temperature than a desired temperature, and thus, a desired processing rate may not be obtained. Further, when it requires an extended time to the main ejection after stopping the dummy ejection, the fluctuation of the flow rate increases at the time of restarting the supply of the processing liquid to the nozzle, and thus, an appropriate flow rate may not be maintained.

In order to deal with the above problem, the flow rate and temperature of the processing liquid are adjusted while supplying the processing liquid in advance to a dummy dispense pot provided at the standby position in a state where the nozzle that ejects the processing liquid is at the standby position (see, e.g., Japanese Patent Laid-Open Publication No. 2007-258462). However, in this case, even if the processing liquid is ejected from the nozzle at the standby position, when performing the main ejection after the ejection of the processing liquid is stopped, the nozzle needs to be swung and moved to the ejection position which is an upper side of the rotation center of the substrate. For this reason, similar to the above case, the problem of temperature drop and flow rate fluctuation occurs when the processing liquid is ejected again from the nozzle.

The embodiments of the present disclosure provide a substrate processing apparatus and a substrate processing method capable of switching from the dummy ejection to the main ejection in a relatively short time, and maintain the processing liquid at a desired flow rate and temperature.

A substrate processing apparatus according to the embodiments of the present disclosure include: a rotating unit that holds and rotates a substrate; a processing liquid supply that supplies a processing liquid from an ejecting unit to a target surface of the substrate rotated by the rotating unit so as to process the substrate; and a receiving unit including a container having an open top, and relatively movable with respect to the ejecting unit between a block position where the container blocks a supply of the processing liquid from the ejecting unit to the substrate and an allowance position where the container allows the supply of the processing liquid from the ejecting unit to the substrate.

A substrate processing method according to the embodiments of the present disclosure processes a substrate by supplying a processing liquid from an ejecting unit of a processing liquid supply to a target surface of the substrate rotated by a rotating unit. A receiving unit including a container having an open top is moved to a block position. The processing liquid is ejected from the ejecting unit. The container blocks the supply of the processing liquid ejected from the ejecting unit to the substrate. A flow rate adjusting unit and a temperature adjusting unit adjust a flow rate and a temperature of the processing liquid ejected from the ejecting unit, respectively. The processing liquid is supplied from the ejecting unit to the target surface of the substrate by relatively moving the container to an allowance position.

The embodiments of the present disclosure may provide a substrate processing apparatus and a substrate processing method capable of switching from the dummy ejection to the main ejection in a relatively short time, and maintaining the processing liquid at a desired flow rate and temperature.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is schematic configuration view illustrating a substrate processing apparatus according to a first embodiment.

FIGS. 2A to 2C are schematic configuration views of the substrate processing apparatus in FIG. 1 illustrating a state where an ejecting unit and a container are at a standby position (FIG. 2A), a state of being moved while maintaining a block position (FIG. 2B), and a state of being at an allowance position (FIG. 2C).

FIGS. 3A to 3F are views illustrating the ejecting unit and the container displaced between the block position and the allowance position.

FIGS. 4A to 4C are views illustrating a state where a processing liquid is attached to an inclined surface of the container (FIG. 4A), a state where the processing liquid is attached to a side surface of the container in a vertical direction (FIG. 4B), and Modification of the container (FIG. 4C).

FIGS. 5A and 5B are schematic configuration views of a substrate processing apparatus according to a second embodiment illustrating a state where a container is at a standby position (FIG. 5A), and a state where the container is at a block position (FIG. 5B).

FIGS. 6A and 6B are schematic configuration views of the substrate processing apparatus according to the second embodiment illustrating a state where an ejecting unit performs a dummy ejection (FIG. 6A), and a state where the ejecting unit performs a main ejection (FIG. 6B).

FIG. 7 is a perspective view illustrating Modification in which a sub-receiving unit is provided in the container.

FIGS. 8A to 8C are views illustrating an operation of Modification in FIG. 7.

FIGS. 9A to 9C are views illustrating Modification in which a penetrating hole is formed in the container.

FIGS. 10A to 10C are views illustrating Modification in which a groove is formed in the container.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

Hereinafter, embodiments of the present disclosure will be described with reference to the drawings.

### First Embodiment

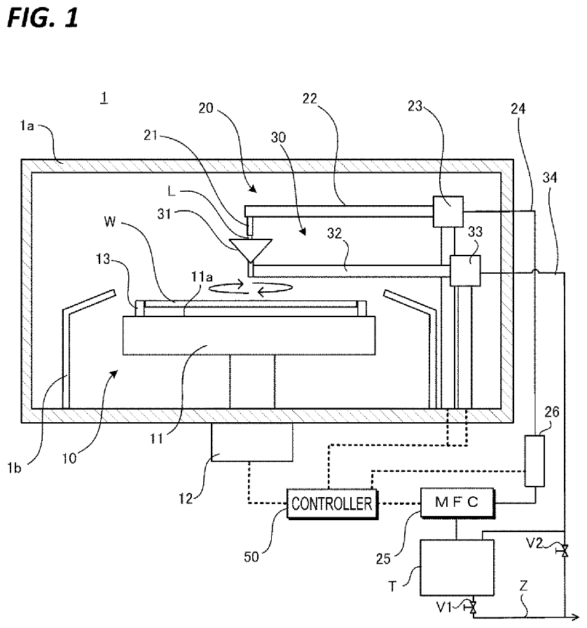

As illustrated in FIG. 1, a substrate processing apparatus 1 according to a first embodiment is a single-wafer processing apparatus including a chamber 1a that is a box-shaped container, and processing a plurality of substrates W, which is transferred in a state of being accommodated in a cassette (FOUP) in a previous process, one by one in the chamber 1a. The substrates W are taken out from the cassette by a transfer robot one by one, temporarily placed on a buffer unit, and then, transferred to the chamber 1a and processed. The substrate W processed by the present embodiment is, for example, a semiconductor wafer. Hereinafter, the surface on which a pattern of the substrate W is formed is referred to as a target surface.

The substrate processing apparatus 1 is, for example, an etching apparatus that supplies the processing liquid L to the rotating substrate W so as to remove an unnecessary film while leaving a circuit pattern. In the present embodiment, as for the processing liquid L, an aqueous solution containing phosphoric acid (H₃PO₄) (hereinafter, referred to as a phosphoric acid solution) may be used. The phosphoric acid solution needs to be heated to a relatively high temperature in order to secure a processing rate, and it is highly necessary to prevent a temperature drop. However, the processing liquid L that is used is not limited thereto, and for example, an acid-based liquid such as a mixed solution of hydrofluoric acid and nitric acid, and a mixed solution of acetic acid, sulfuric acid, and hydrogen peroxide (sulfuric acid-hydrogen peroxide mixture: SPM) may be widely used.

As illustrated in FIG. 1 to FIGS. 3A to 3F, the substrate processing apparatus 1 includes a rotating unit 10, a processing liquid supply unit 20, a receiving unit 30, and a controller 50.

### Rotating Unit

The rotating unit 10 holds and rotates the substrate W. The rotating unit 10 includes a rotating body 11, a driving source 12, and a supporting unit 13. The rotating body 11 includes a facing surface 11a that faces the substrate W with an interval (e.g., a gap). The rotating body 11 has a cylindrical shape with one end closed by the facing surface 11a. The facing surface 11a is a circular surface having a diameter larger than that of the substrate W. The rotating body 11 is made of a material resistant to the processing liquid L. For example, the rotating body 11 may be made of a fluorine-based resin such as PTFE or PCTFE.

The driving source 12 rotates the rotating body 11. The driving source 12 may be a motor, and is provided on an installation surface (not illustrated) or on a base (not illustrated) fixed to a frame installed to the installation surface. A cover 1b that receives the processing liquid L scattered from the rotating substrate W around the substrate W is provided around the rotating body 11 in the chamber 1a. That is, the cover 1b has a cylindrical shape surrounding the rotating body 11 and the substrate W, and the upper portion of the cylindrical shape is inclined toward the side of the rotating body 11 and the substrate W.

The supporting unit 13 supports the substrate W on the rotating body 11. A plurality of supporting units 13 is provided in a peripheral edge of the substrate W, and is provided to be movable between a closed position in contact with an edge portion of the substrate W and an open position separated from the edge portion of the substrate W, by an opening/closing mechanism (not illustrated). The supporting unit 13 supports the substrate W in parallel with the facing surface 11a with an interval (e.g., a gap). The surface of the substrate W on the opposite side to the surface on the facing surface 11a side becomes the target surface.

### Processing Liquid Supply

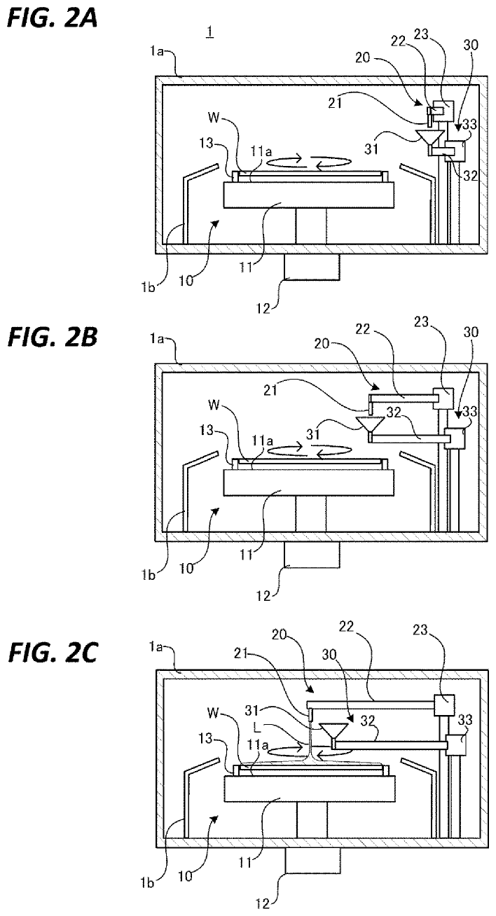

As illustrated in FIG. 2C, the processing liquid supply unit 20 supplies the processing liquid L from the ejecting unit 21 to the target surface of the substrate W rotated by the rotating body 11 to process the substrate W. In the present embodiment, the processing liquid supply unit 20 performs an etching processing by supplying the processing liquid L, which is a phosphoric acid solution, to the target surface of the substrate W held by the supporting unit 13.

The processing liquid supply unit 20 includes the ejecting unit 21, a swing arm 22, and a swing mechanism 23. The ejecting unit 21 is a nozzle that supplies the processing liquid L toward the vicinity of the center of the target surface of the substrate W. A phosphoric acid solution, which is the processing liquid L, is supplied from a tank T outside the chamber 1a to the ejecting unit 21 via a pipe 24. In the pipe 24 serving as a supply path of the processing liquid L, a mass flow controller (MFC) 25 and a heater 26 are provided. The flow rate of the processing liquid L is adjusted by the MFC 25 serving as a flow rate adjusting unit, and the temperature of the processing liquid L is adjusted by the heater 26 serving as a temperature adjusting unit. The MFC 25 includes a built-in flow rate sensor therein, and controls a flow rate valve based on the flow rate detected by the flow rate sensor and the feedback of the set flow rate. A temperature sensor (not illustrated) is provided in the pipe 24, and a control on the temperature of the heater 26 or whether or not the processing liquid L is ejected is performed based on the temperature detected by the temperature sensor. Further, a drainage path Z of the processing liquid L is connected to the tank T, and a switching control between whether to drain or not may be performed by opening/closing of a valve V1.

The swing arm 22 is provided with the ejecting unit 21 at the tip thereof. The ejecting unit 21 is a so-called nozzle. The swing arm 22 is provided to be swingable between an ejection position (e.g., FIG. 1 and FIG. 2C) where the ejecting unit 21 ejects the processing liquid L onto the target surface of the substrate W and a standby position (e.g., FIG. 2A) that is deviated from an upper side of the target surface of the substrate W. The ejection position of the present embodiment is located immediately above the position corresponding to the rotation center of the target surface of the substrate W on the rotating body 11. The standby position is a position that is retracted from the ejection position so as to make it possible to carry in or carry out the substrate W. The standby position may be deviated from an upper side of the target surface of the substrate W, and may be outside the cover 1b.

The swing mechanism 23 is a mechanism that swings the swing arm 22 so that the ejecting unit 21 is moved between the ejection position and the standby position. Further, the swing mechanism 23 is moved vertically so as to move the ejecting unit 21 in a direction of contacting with and separating from the substrate W.

### Receiving Unit

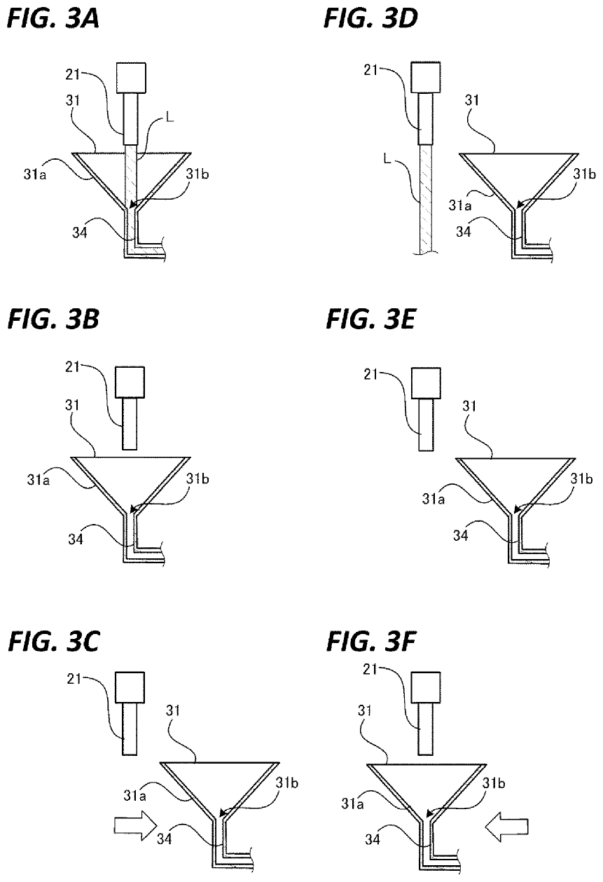

The receiving unit 30 includes a container 31 having an open top, a swing arm 32, a swing mechanism 33, and a recovery path 34. The container 31 is relatively movable with respect to the ejecting unit 21 between a block position (e.g., FIG. 1, FIGS. 2A and 2B, and FIG. 3A) where the supply of the processing liquid L from the ejecting unit 21 to the substrate W is blocked, and an allowance position (e.g., FIG. 2C and FIG. 3D) where the supply of the processing liquid L from the ejecting unit 21 to the substrate W is allowed, by the swing arm 32 and the swing mechanism 33. Further, the container 31 is movable to the standby position deviated from an upper side of the target surface of the substrate W. The standby position may be outside the cover 1b.

The block position is a position where the container 31 of the receiving unit 30 is positioned at a lower side (e.g., immediately below) of the ejecting unit 21, and the processing liquid L is received. Further, the block position is not an absolute position in the substrate processing apparatus 1, and may be movable when the ejecting unit 21 is moved. That is, the block position is a relative position with respect to the position of the ejecting unit 21.

The allowance position is a position where the container 31 of the receiving unit 30 is deviated from a lower side (e.g., immediately below) of the ejecting unit 21, and the processing liquid L is not received. That is, when the container 31 is positioned at the allowance position, the ejecting unit 21 is located outside from the outermost end (e.g., an edge portion) of the container 31, and thus, the ejection of the processing liquid L is not hindered. The allowance position is also not an absolute position in the substrate processing apparatus 1, but may be a position determined relatively with respect to the position of the ejecting unit 21. Further, the allowance position may be any position as long as the container 31 is deviated from the ejecting unit 21 and the ejection of the processing liquid L is not hindered. The allowance position may be a predetermined position with respect to the position of the ejecting unit 21, and may be one location or a plurality of locations. For example, when the container 31 is returning to the standby position while ejecting the processing liquid L from the ejecting unit 21, the standby position becomes the allowance position.

However, in the present embodiment, as illustrated in FIG. 2C, while the processing liquid L is ejected from the ejecting unit 21 toward the target surface of the substrate W, the container 31 at the allowance position is positioned near the ejecting unit 21. As described above, when the allowance position is located near the ejecting unit 21, the container 31 may be moved to be positioned at the block position in a relatively short time after the ejection of the processing liquid L from the ejecting unit 21 is ended. Therefore, even if the processing liquid L drips from the ejecting unit 21 at the end of the ejection, the dropped liquid may be prevented from falling onto the substrate W. As a result, the container 31 may be positioned near the ejecting unit 21 while the processing liquid L is being ejected from the ejecting unit 21 toward the target surface of the substrate W. Alternatively, as described above, the container 31 may be positioned at the standby position while the processing liquid L is being ejected from the ejecting unit 21. In this case, the container 31 may be positioned near the ejecting unit 21 when the ejection from the ejecting unit 21 is stopped or immediately before stopping the ejection.

The container 31 is an inverted conical shape member having an open top. As a result, when the container 31 is relatively moved from the block position to the allowance position, as illustrated in FIGS. 3A to 3F, the outer surface of the container 31 passing the lower side of the ejecting unit 21 is an inclined surface 31a that is inclined such that the block position side faces downward. Further, a recovery port 31b is provided in the lower portion of the container 31. The container 31 is made of a material resistant to the processing liquid L. For example, the container 31 may be made of a fluorine-based resin such as PTFE or PCTFE.

As illustrated in FIG. 1 and FIGS. 2A to 2C, the swing arm 32 is provided with the container 31 at the tip thereof. The container 31 is provided to be movable between the block position and the allowance position by the swing arm 32.

The swing mechanism 33 is a mechanism that swings the swing arm 32 so that the container 31 is moved between the block position and the allowance position. Further, the swing mechanism 33 moves the container 31 to the standby position. Further, the swing mechanism 33 is moved in a vertical direction so as to move the container 31 in a direction of contacting with and separating from the substrate W. The recovery path 34 connected to the recovery port 31b is provided in the swing arm 32 and the swing mechanism 33. The recovery path 34 is disposed along the swing arm 32, and extends to the tank T outside the chamber 1a. Therefore, a path is configured through which the processing liquid L recovered to the container 31 is returned to the tank T through the recovery path 34. Further, the recovery path 34 is branched into pipes provided with a valve V2, and is connected to the drainage path Z. Therefore, a path is configured through which the processing liquid L recovered to the container 31 is discharged through the recovery path 34 and the drainage path Z.

In FIG. 1 and FIGS. 2A to 2C, for the sake of clarity, the swing arm 22 and the swing arm 32 are illustrated such that the positions of the shafts that are swung are shifted from each other for the sake of convenience, and the horizontal lengths of both of the swing arm 22 and the swing arm 32 are different from each other. However, since the container 31 of the receiving unit 30 is moved together with the ejecting unit 21 while maintaining the block position, the swing shafts of the swing arm 22 and the swing arm 32 are actually coaxial, and the horizontal lengths are the same. Further, the length of the swing arm 32 may be configured to be extendable. Therefore, the swing arm 32 is swung and extends on the swing trajectory of the swing arm 22, and thus, the container 31 and the ejecting unit 21 may be moved together.

Although not illustrated, the substrate processing apparatus 1 is provided with a cleaning liquid supply nozzle that is movable to the rotation center of the substrate W by the swing mechanism and supplies carbonated water, warm pure water (DIW), and a mixed solution of ammonia water-hydrogen peroxide (ammonia-hydrogen peroxide mixture: APM) as a cleaning liquid. For example, before the etching by a phosphoric acid solution, carbonated water may be supplied from the cleaning liquid supply nozzle to the target surface of the substrate W to perform a cleaning process for the substrate W. After the etching, the APM may be supplied from the cleaning liquid supply nozzle to the target surface of the substrate W, so that the remaining organic matter may be removed. Further, the DIW is supplied from the cleaning liquid supply nozzle to the target surface of the substrate W, so that the APM is replaced with the DIW.

### Controller

The controller 50 controls each part of the substrate processing apparatus 1. The controller 50 includes a processor that executes a program, a memory that stores the program or various information such as an operation condition, and a driving circuit that drives each element in order to implement various functions of the substrate processing apparatus 1. The controller 50 includes an input device that inputs information and a display device that displays information. The controller 50 of the present embodiment controls the driving source 12, supporting unit 13, swing mechanisms 23 and 33, MFC 25, and heater 26. In particular, as will be described below, the controller 50 controls the flow rate and temperature of the processing liquid L by controlling the MFC 25 and heater 26 based on the values detected by the flow rate sensor and temperature sensor.

### Operation

An operation of the substrate processing apparatus 1 of the present embodiment as described above will be described with reference to FIG. 1 to FIGS. 3A to 3F. A substrate processing method that processes the substrate W according to the following procedure is one aspect of the present embodiment as well.

First, the substrate W, which is a processing target, is carried onto the rotating body 11 by the transfer robot, and is held by the supporting unit 13. The rotating body 11 is rotated at a predetermined speed (e.g., approximately 200 rpm to 300 rpm) which is relatively high so as to rotate the substrate W, and carbonated water is supplied from the cleaning liquid supply nozzle to the target surface of the substrate W, so that the target surface is cleaned. Then, the rotating body 11 is rotated at a predetermined speed (e.g., approximately 50 rpm) which is relatively low, so that the substrate W is rotated at the predetermined speed.

Meanwhile, as illustrated in FIG. 2A, the ejecting unit 21 of the processing liquid supply unit 20 is at the standby position deviated from an upper side of the target surface of the substrate W. Further, the container 31 of the receiving unit 30 is at the standby position deviated from an upper side of the target surface of the substrate W, and at the same time, positioned at the block position where the supply of the processing liquid L from the ejecting unit 21 to the substrate W is blocked. That is, the opening of the upper portion of the container 31 is located at a lower side of the ejecting unit 21, and thus, the container 31 is at the position where the processing liquid L ejected from the ejecting unit 21 falls into the container 31.

As described above, the ejecting unit 21 and the container 31 are moved together with or at the same time to the ejection position as illustrated in FIG. 1 from a state where the ejecting unit 21 and the container 31 are at the standby position, the container 31 maintains the state of being at the block position as illustrated in FIG. 2B, and the swing arm 22 and swing arm 32 are swung together with or at the same time. That is, the ejecting unit 21 is positioned immediately above the position corresponding to the rotation center of the substrate W. As described above, the falling of the processing liquid L remaining in the ejecting unit 21 is prevented by the container 31 during the movement of the ejecting unit 21 and the container 31.

Then, when the supply of the processing liquid L from the tank T is started, as illustrated in FIG. 1 and FIG. 3A, the processing liquid L is continuously ejected from an ejection port of the ejecting unit 21 into the container 31. That is, the dummy ejection is performed in a state where the processing liquid L ejected from the ejecting unit 21 is prevented from falling onto the substrate W by the container 31. As described above, the flow rate is adjusted by the MFC 25 and the temperature is adjusted by the heater 26 while the processing liquid L is being ejected from the ejecting unit 21. For example, in a case of phosphoric acid solution, the temperature is adjusted between 150° C. to 160° C. The processing liquid L ejected into the container 31 is recovered via the recovery port 31b and the recovery path 34.

As described above, a determination is made whether or not the processing liquid L reaches a desired temperature based on the temperature detected by the temperature sensor provided in the pipe 24. That is, when the temperature detected by the temperature sensor reaches a desired temperature, the dummy ejection from the ejecting unit 21 is stopped. Further, after starting the ejection, it takes a certain time until the flow rate detected by the flow rate sensor of the MFC 25 reaches a set flow rate to be stabilized, but the desired flow rate is reached by continuing the ejection of the processing liquid L until the desired temperature is reached, and thus, the flow rate may be also adjusted at the same time as the temperature is adjusted.

The temperature sensor may be provided inside the container 31. That is, in the container 31, the temperature sensor may protrude at the position where the processing liquid L is ejected, and control may be performed such that the temperature is detected by the temperature sensor and, when the desired temperature is reached, the ejection of the processing liquid L is temporarily stopped. Further, without providing the temperature sensor, the processing liquid L may be ejected until a predetermined time is reached. That is, the time required to reach the desired temperature is calculated in advance through an experiment, and when that time elapses, the ejection may be stopped by assuming that the processing liquid L at the desired temperature is being ejected.

When the processing liquid L reaches the desired flow rate and temperature, as illustrated in FIG. 3B, the ejection of the processing liquid L from the ejecting unit 21 is stopped. Then, as illustrated in FIG. 3C, the container 31 is moved to the allowance position. Then, as illustrated in FIG. 2C and FIG. 3D, the ejection of the processing liquid L with the flow rate and the temperature adjusted as described above is restarted from the ejecting unit 21, and the processing liquid L is supplied to the substrate W. The stop time of the ejection at the time of displacement from the block position to the allowance position is, for example, within 5 seconds, and may be within 3 seconds. As described above, since the time from the stop of the ejection of the processing liquid L to the restarting of the ejection is extremely short, it is possible to shorten the time during which the flow of the processing liquid L is stopped and the processing liquid L stays in the pipe, and the fluctuation of the flow rate and temperature drop at the start of the supply of the processing liquid L to the substrate W are suppressed. When the ejection is restarted, although the container 31 is not completely moved to the position regarded as the allowance position, it is sufficient that the container 31 is deviated from a lower side of the ejecting unit 21.

The processing liquid L ejected from the ejecting unit 21 at the desired flow rate and temperature is supplied to the substrate W to process the target surface of the substrate W. That is, the main ejection for processing the target surface of the substrate W is performed. For example, when the phosphoric acid solution is continuously supplied from the ejecting unit 21 to the center of the target surface of the substrate W, the phosphoric acid solution is sequentially moved toward the outer periphery of the rotating substrate W, and thus, a portion of the nitride film is etched and removed while the carbonated water on the target surface is replaced by the phosphoric acid solution. When a predetermined processing time elapses, as illustrated in FIG. 3E, the processing liquid supply unit 20 stops the supply of the processing liquid L.

Thereafter, as illustrated in FIG. 1 and FIG. 3F, after moving the container 31 to the block position by swinging the swing arm 32, the container 31 is moved to the standby position together with the ejecting unit 21 as illustrated in FIG. 2A, by swinging the swing arm 22 and swing arm 32 while maintaining the block position as illustrated in FIG. 2B. The falling of the processing liquid L remaining in the ejecting unit 21 is prevented by the container 31 during the movement of the ejecting unit 21 and the container 31.

When the etching processing is ended, the rotating body 11 is rotated at a predetermined speed (e.g., approximately 200 rpm to 300 rpm) which is relatively high, and the cleaning liquid supply unit supplies the warm pure water to the target surface of the substrate W, and thus, the phosphoric acid solution on the substrate W is replaced with the warm pure water. Thereafter, the rotation of the substrate W is stopped, and the substrate W released from the supporting unit 13 is carried out from the chamber 1a by the transfer robot.

As the time during which the processing liquid L is not ejected increases, the temperature of the pipe 24 is decreased. Due to this, the temperature of the processing liquid L at the time of ejection is also decreased. Further, even when the supply of the processing liquid L to the substrate W is completed so that the ejection is stopped, the temperature of the processing liquid L remaining in the pipe 24 is decreased as the time elapses. As a result, for example, the dummy ejection may be performed when the substrate W is processed for the first time, or when a predetermined time or more elapses between the completion of the processing of the substrate W and the time at which the next substrate W is carried in.

Further, it may be determined whether or not the next substrate W is carried in within a predetermined time, and a determination whether or not the dummy ejection is to be performed may be made at that timing. For example, when it is determined that the substrate W is not carried in within a predetermined time, the dummy ejection is performed after waiting until the next substrate W is processed. Therefore, it is not necessary to perform the dummy ejection every time the substrate W is processed. An operator may determine whether or not the next substrate W is carried in within a predetermined time, or the controller 50 may determine based on whether or not a predetermined time has elapsed without receiving a signal notifying that the substrate W is transferred from the apparatus of the previous process. Further, the controller 50 may calculate the time required for the substrate W to be transferred to the substrate processing apparatus 1 based on the signal sent from the apparatus of the previous process, and may determine whether or not the dummy ejection is performed based on the calculated time.

### Effect

(1) The substrate processing apparatus 1 of the present embodiment includes: the rotating unit 10 that holds and rotates the substrate W; the processing liquid supply unit 20 that supplies the processing liquid L from the ejecting unit 21 to the target surface of the substrate W rotated by the rotating unit 10 so as to process the substrate W; and the receiving unit 30 including the container 31 having an open top, and relatively movable with respect to the ejecting unit 21 between the block position where the supply of the processing liquid L from the ejecting unit 21 is blocked and the allowance position where the supply of the processing liquid L from the ejecting unit 21 is allowed.

A substrate processing method of the present embodiment processes the substrate W by supplying the processing liquid L from the ejecting unit 21 of the processing liquid supply unit 20 to the target surface of the substrate W rotated by the rotating unit 10. The receiving unit 30 including the container 31 having the open top is moved to the block position. The processing liquid L is ejected from the ejecting unit 21. The container 31 blocks the supply of the processing liquid L ejected from the ejecting unit 21 to the substrate W. The MFC 25 serving as the flow rate adjusting unit and the heater 26 serving as the temperature adjusting unit adjust the flow rate and the temperature of the processing liquid L ejected from the ejecting unit 21, respectively. The processing liquid L is supplied from the ejecting unit 21 to the target surface of the substrate W by relatively moving the container 31 to the allowance position.

As a result, after performing the dummy ejection at an upper side of the substrate W which will become a product, it is possible to switch to the main ejection in a relatively short time, and thus, it becomes easy to maintain the flow rate and temperature of the processing liquid L after the adjustment. As a result, it is not necessary to adjust the flow rate and the temperature of the processing liquid L using the dummy substrate while suppressing the decrease of the processing rate, and thus, the time required to carry in and carry out the dummy substrate is not required, which may increase the throughput. Further, since the container 31 and the ejecting unit 21 are relatively moved at an upper side of the substrate W to switch from the dummy ejection position to the main ejection position, the travel distance becomes relatively short, so that the switch may be performed in a relatively short time.

Further, it is possible to move the receiving unit 30 from the allowance position to the block position in a relatively short time after the end of the ejection from the ejecting unit 21, and thus, the processing liquid L that drips from the nozzle after the end of the ejection may be received, so that the processing liquid L may be prevented from falling to the substrate W.

(2) The ejecting unit 21 is provided to be movable between the ejection position where the processing liquid L is ejected onto the target surface of the substrate W and the standby position deviated from an upper side of the target surface of the substrate W, and the receiving unit 30 is provided to be movable from the ejecting position to the standby position while maintaining the block position. As a result, after the processing liquid L is supplied to the substrate W, the processing liquid L is prevented from falling from the ejecting unit 21 and adhering to the substrate W, and thus, the uniformity of the processing of the target surface of the substrate W is maintained.

(3) The receiving unit 30 is provided to be movable to the ejection position together with the ejecting unit 21 while maintaining the block position. As a result, the processing liquid L is prevented from falling from the ejecting unit 21 to the target surface of the substrate W when being moved to the ejecting position, and the deterioration of the quality due to the partial processing of the substrate W before the processing may be prevented.

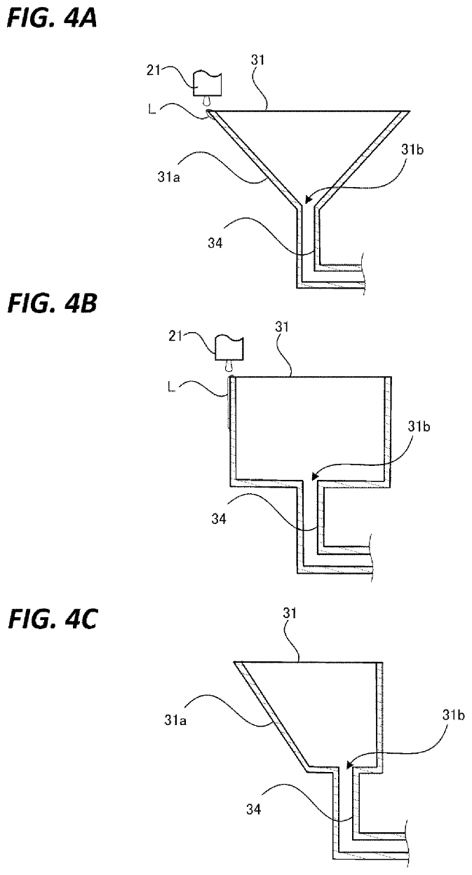

(4) When the container 31 is relatively moved from the block position to the allowance position, the outer surface of the container 31 passing a lower side of the ejecting unit 21 is the inclined surface 31a that is inclined such that the block position side faces downward. As a result, as illustrated in FIG. 4A, even when the processing liquid L is dropped from the ejecting unit 21 to the upper edge of the container 31, the adhesion amount may be reduced as compared to the case of the surface in the vertical direction illustrated in FIG. 4B. Therefore, the side surface of the container 31 may be prevented from being soiled, and the processing liquid L is less likely to drip. Further, as illustrated in FIG. 4C, a portion of the outer surface of the container 31 may be the inclined surface 31a.

### Second Embodiment

### Configuration

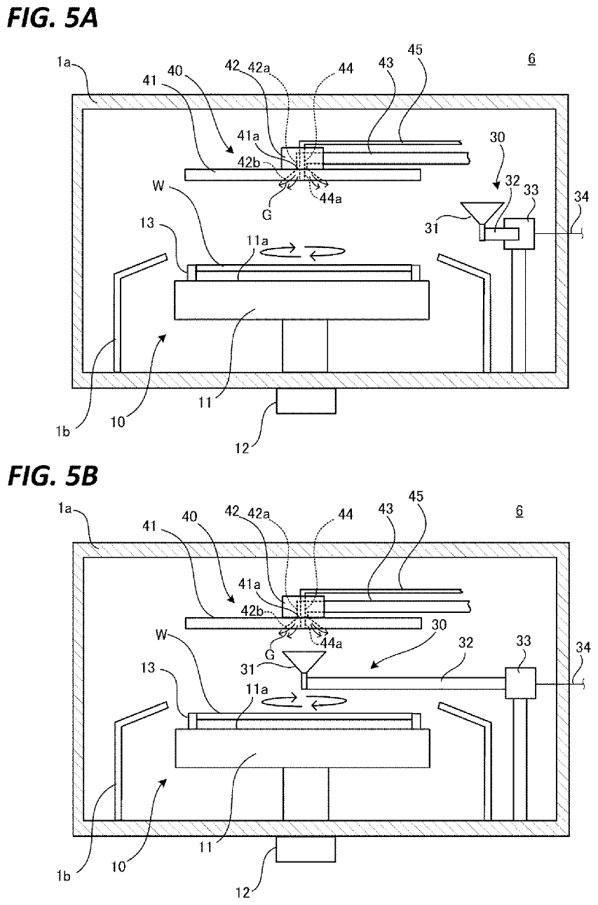

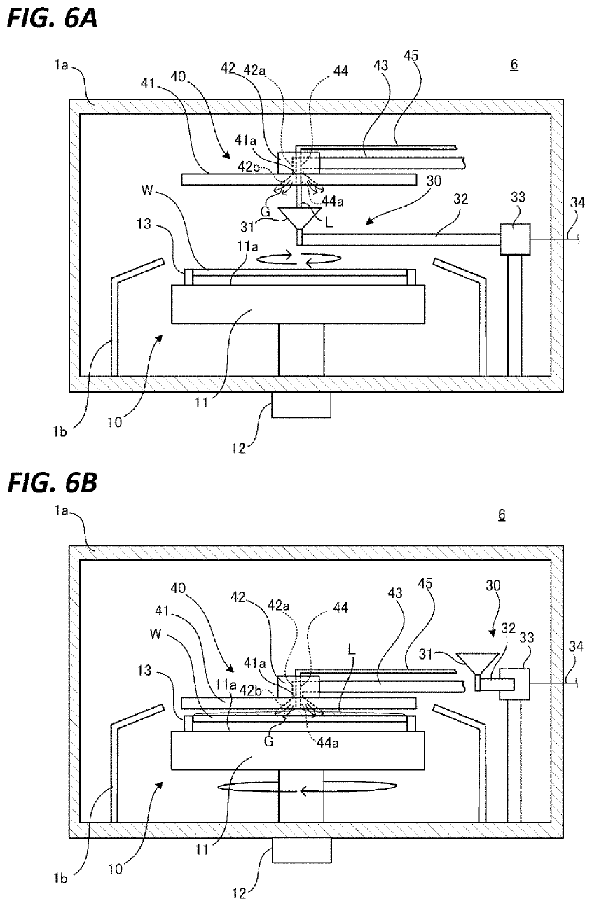

A second embodiment of the present disclosure will be described with reference to FIGS. 5A and 5B and FIGS. 6A and 6B. The configuration of the present embodiment is similar to that of the first embodiment as described above, and the same members are denoted by the same reference numerals, and description thereof is omitted. However, a substrate processing apparatus 6 of the present embodiment is a drying apparatus that dries the substrate W by supplying a volatile processing liquid L after cleaning the target surface of the substrate W, and a shielding unit 40 is provided on the supply side of the processing liquid L. The shielding unit 40 is provided to be movable in a direction of contacting with and separating from the rotating unit 10, and faces the substrate W in a non-contact manner.

The shielding unit 40 includes a shielding plate 41 and a base unit 42. The shielding plate 41 is a disc-shaped member having a diameter larger than that of the substrate W. An opening 41a is provided in the center of the shielding plate 41. The base unit 42 is a column-shaped member, and is provided to be vertically movable by an elevation mechanism (not illustrated). The shielding plate 41 is coaxially provided at the bottom of the base unit 42.

The base unit 42 is provided with a gas flow path 42a through which a gas G flows. One end of the gas flow path 42a reaches the side surface of the base unit 42 and is connected to a pipe 43 which is connected to a gas supply source (not illustrated). The gas G is used to purge the air on the surface of the substrate W, thereby preventing a water mark generated due to a combination of water on the surface of the substrate W and oxygen in the air. As for the gas G in the present embodiment, for example, a rare gas such as N2 is used. The other end of the gas flow path 42a is expanded in diameter, and reaches the opening 41a of the shielding plate 41 to serve as a gas supply 42b. Therefore, the gas G from the gas supply source may be supplied from the center of the shielding plate 41 to the target surface of the substrate W through the gas flow path 42a.

Further, the base unit 42 is provided with a processing liquid supply unit 44 through which the processing liquid L flows. The processing liquid supply unit 44 reaches the upper portion of the base unit 42, and is connected to a pipe 45 of a liquid supply source (not illustrated) of the processing liquid L. The flow rate and temperature of the processing liquid L are adjusted by the MFC 25 and the heater 26, respectively, as in the first embodiment described above.

As for the processing liquid L flowing through the processing liquid supply unit 44 of the present embodiment, for example, a volatile solvent such as isopropyl alcohol (IPA) is used. Since IPA has a relatively low surface tension, the collapse of the pattern of the substrate W due to the surface tension is less likely to occur when the IPA is evaporated. The other end of the processing liquid supply unit 44 airtightly penetrates the gas flow path 42a, and reaches the opening 41a of the shielding plate 41 to serve as the ejecting unit 44a, which is a nozzle. Therefore, the processing liquid L from the liquid supply source may be supplied from the ejecting unit 44a at the center of the shielding plate 41 to the target surface of the substrate W through the processing liquid supply unit 44.

Although not illustrated, the substrate processing apparatus 6 is provided with a cleaning liquid supply nozzle that supplies warm pure water (DIW), a processing liquid supply nozzle that supplies a mixed solution of hydrochloric acid-hydrogen peroxide (hydrochloric acid-hydrogen peroxide mixture: HPM), and a processing liquid supply nozzle that supplies a mixed solution of ammonia water-hydrogen peroxide (APM) to be movable to the rotation center of the substrate W by the swing mechanism.

### Operation

An operation of the substrate processing apparatus 6 of the present embodiment as described above will be described with reference to FIGS. 5A and 5B and FIGS. 6A and 6B. A substrate processing method that processes the substrate W according to the following procedure is also one aspect of the present embodiment.

First, the substrate W, which is a processing target, is carried onto the rotating body 11 by the transfer robot, and is held by the supporting unit 13. Then, while the rotating body 11 is rotated at a predetermined speed (e.g., approximately 200 rpm to 300 rpm) which is relatively high, N2 gas serving as the gas G is supplied from the center of the shielding plate 41 to the target surface of the rotated substrate W through the gas flow path 42a, and the DIW, the HPM, the DIW, the APM, and the DIW are supplied in this order from the cleaning liquid supply nozzle and the processing supply nozzle. Therefore, the target surface of the substrate W is cleaned and filled with the DIW.

Next, as illustrated in FIG. 5A, from the state where the container 31 is in the standby position deviated from an upper side of the target surface of the substrate W and a lower side of the shielding plate 41, the swing arm 32 is swung, and, as illustrated in FIG. 5B, the container is moved to the block position. The block position is a position where the container 31 is positioned at a lower side (immediately below) of the ejecting unit 44a, and the processing liquid L is received. Therefore, the container 31 is moved immediately above the position corresponding to the rotation center of the substrate W. In the present embodiment, the allowance position is also a position where the container 31 is deviated from the lower side (immediately below) of the ejecting unit 44a such that the processing liquid L may not be received.

Then, when the supply of the processing liquid L from the tank T is started, as illustrated in FIG. 6A, the processing liquid L is continuously ejected from an ejection port of the ejecting unit 44a into the container 31. That is, the dummy ejection is performed in a state where the processing liquid L ejected from the ejecting unit 44a is prevented from falling onto the substrate W by the container 31. As described above, while ejecting the processing liquid L from the ejecting unit 44a, the flow rate is adjusted by the MFC 25, and the temperature is adjusted by the heater 26. For example, in a case of the IPA, the temperature is adjusted to approximately 50° C. The processing liquid L ejected into the container 31 is recovered via the recovery port 31b and the recovery path 34.

When the processing liquid L reaches the desired flow rate and temperature, the ejection of the processing liquid L from the ejecting unit 44a is stopped. Then, as illustrated in FIG. 5A, the container 31 is moved to the standby position. Next, as illustrated in FIG. 6B, the shielding unit 40 is lowered, and thus, the shielding plate 41 approaches the target surface of the substrate W and stops at a distance of approximately several millimeters. Since N2 gas is supplied in the gas flow path 42a, the N2 gas spouted from the gas supply 42b flows through the narrow area between the target surface of the substrate W and the shielding plate 41, so that the air containing oxygen is purged.

At the same time, the ejection of the processing liquid L from the ejecting unit 44a is started again, and the processing liquid L is supplied to the substrate W. The stop time of the ejection therebetween is the same as the first embodiment as described above. In the present embodiment, the operation in which the container 31 is moved to the standby position deviated from a lower side of the shielding plate 41 and the shielding plate 41 is lowered is required, but also in this case, the stop time of the supply may be within 5 seconds. As described above, the processing liquid L ejected from the ejecting unit 44a is supplied to the substrate W at the desired flow rate and temperature, and thus, the warm pure water (DIW) is replaced with the processing liquid L. That is, the main ejection for processing the target surface of the substrate W is performed.

For example, when the IPA from the ejecting unit 44a is continuously supplied to the center of the target surface of the substrate W, the IPA is sequentially moved toward the outer periphery of the rotating substrate W, and thus, the warm pure water (DIW) on the target surface is replaced with the IPA. When a predetermined processing time elapses, the processing liquid supply unit 20 stops the supply of the processing liquid L. Since the IPA on the rotating substrate W is evaporated and disappeared, the target surface of the substrate W is dried.

When the target surface of the substrate W is dried, the shielding unit 40 is raised, and the supply of the gas G is stopped and the rotation of the substrate W is stopped. Thereafter, the substrate W released from the supporting unit 13 is carried out from the chamber 1a by the transfer robot.

### Effect

The substrate processing apparatus 6 of the present embodiment includes the shielding unit 40 provided to be movable in a direction of contacting with and separating from the rotating unit 10, and facing the substrate W in a non-contact manner. The shielding unit 40 is provided with the ejecting unit 44a that ejects the processing liquid L to the target surface of the substrate W and the gas supply 42b that supplies a gas between the surface of the shielding unit 40 facing the substrate W and the substrate W. Further, the substrate processing apparatus 6 of the present embodiment is provided with the receiving unit 30 that includes the container 31 having an open top, and is relatively movable with respect to the ejecting unit 21 between the block position where the supply of the processing liquid L from the ejecting unit 44a is blocked and the allowance position where the supply of the processing liquid L from the ejecting unit 44a is allowed.

As described above, in the case of the substrate processing apparatus 6 including the shielding unit 40, the ejecting unit 44a is moved in a vertical direction, but is not configured to be swingable. As a result, in the related art, in order to perform the dummy ejection, it is required to use the dummy substrate, and thus, the process in which the dummy substrate is carried in and carried out is required, and, after adjusting the flow rate and temperature of the processing liquid L, the main ejection is required to be performed after the dummy substrate is carried out and the product substrate is carried in. Therefore, since it takes time until the main ejection is performed, the adjusted flow rate and temperature may be changed. Further, it may be conceivable that the shielding unit 40 is configured to be horizontally movable, and in a state where the ejecting unit 44a that includes the shielding unit 40 and ejects the processing liquid L is at the standby position, the flow rate and temperature are adjusted while supplying the processing liquid L in advance to a dummy dispense port provided at the standby position. However, the space required when the shielding unit 40 is horizontally moved to be retracted to the standby position is relatively too large, the chamber 1a itself becomes relatively large, and the substrate processing apparatus 6 becomes relatively large.

In the present embodiment, the dummy ejection may be performed at the ejecting position of the ejecting unit 44a, and thus, the carry-in/out process of the dummy substrate is not required, and the main ejection may be performed immediately after the flow rate and temperature of the processing liquid L are adjusted. That is, the time until the container 31 is retracted and the shielding plate 41 is lowered is a relatively short time that may be considered to be a right after, as compared to the time required for switching from the dummy substrate to the processing substrate. As a result, the throughput may be improved and the decrease of the processing rate may be suppressed by suppressing the change in the flow rate and temperature.

### Modification

In the above-described embodiment, the following Modification may be configured.

(1) The shielding unit 40 and the ejecting unit 44a of the second embodiment may be separate members. That is, the ejecting unit 21 as in the first embodiment may be provided separately from the shielding unit 40. Therefore, the ejecting unit 21 and container 31 may be moved to the standby position while maintaining the block position, so that the falling of the processing liquid L to the substrate W may be prevented.

(2) It is possible to switch to the main ejection by moving the container 31 to the allowance position while performing the dummy ejection to the container 31 positioned at the block position from the ejecting units 21 and 44a positioned at the ejection position. In this case, instead of temporarily stopping the ejection after the dummy ejection and ejecting again at the time of the main ejection, the processing liquid L at the desired flow rate and temperature is continuously ejected. As a result, it is possible to further suppress the change in the flow rate and temperature. Modification described below is also effective in the case of stopping the ejection for the dummy ejection and then starting the main ejection, and in the case of switching from the dummy ejection to the main ejection while continuously performing the ejection.

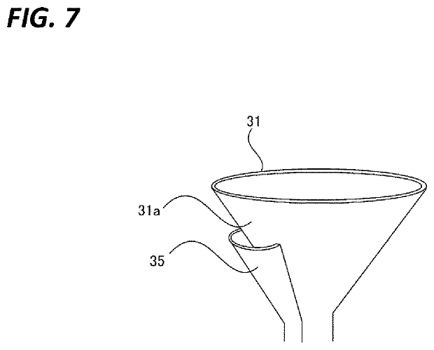

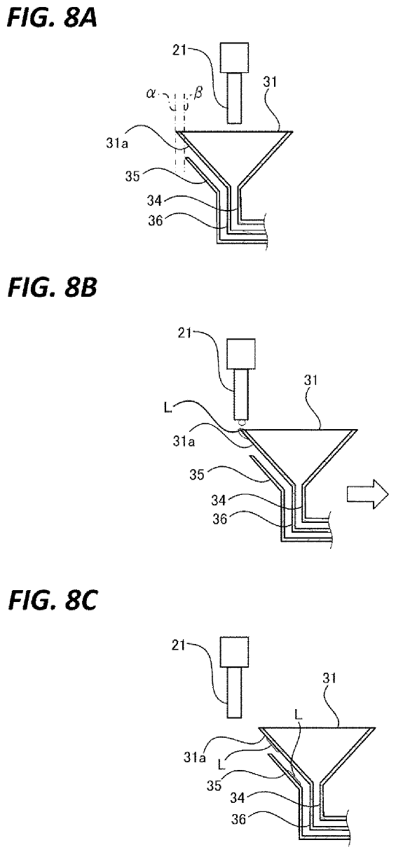

(3) As illustrated in FIG. 7 and FIGS. 8A to 8C, when the container 31 is relatively moved from the block position to the allowance position, a sub-receiving portion 35 that blocks the falling of the processing liquid L flowing on the outer surface to the target surface may be provided on the outer surface of the container 31 passing a lower side of the ejecting unit 21. The sub-receiving portion 35 is formed in a pocket shape to cover a portion of the outer surface of the container 31. The upper edge of the container 31 is on the allowance position side from an upper edge of the sub-receiving portion 35. That is, as illustrated in FIG. 8A, an end portion 13 of the outermost edge of the sub-receiving portion 35 in the horizontal direction is on the inner side from an end portion a of the outermost edge of the container 31 in the horizontal direction. A discharge flow path 36 of the processing liquid L is provided in the lower portion of the sub-receiving portion 35, and joins the recovery path 34 of the container 31.

Therefore, when the container 31 is moved to the allowance position, as illustrated in FIG. 8B, even when the processing liquid L fallen from the ejecting unit 21 adheres to the upper edge of the opening of the container 31 and flows on the outer surface, the fallen liquid flows to the sub-receiving portion 35 as illustrated in FIG. 8C, and thus, the falling to the target surface of the substrate W is prevented. That is, even if the processing liquid L drips to the end portion a of the outermost edge of the container 31 and flows along the side surface of the container 31, the processing liquid L does not fall to the substrate W. As a result, it is possible to prevent deterioration of the quality due to progress of the reaction at the portion where the processing liquid L is fallen on the target surface. This Modification may be applied not only to the first embodiment described above, but to the second embodiment. That is, the container 31 positioned at a lower side of the ejecting unit 44a described above may be provided with the sub-receiving portion 35.

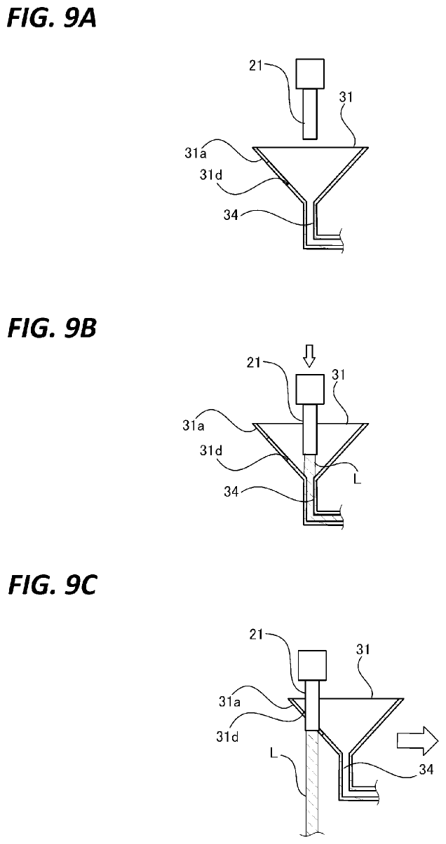

(4) As illustrated in FIG. 9A, a through hole 31d facing the ejecting unit 21 may be formed in the container 31. The through hole 31d is formed in a portion of the side surface (e.g., inclined surface 31a) of the container 31. Further, the diameter of the through hole 31d is larger than the outer diameter of the ejecting unit 21. As a result, even when the ejecting unit 21 is positioned at an upper side of the container 31, as illustrated in FIG. 9C, when the ejecting unit 21 is at the position facing the through hole 31d in the container 31, it becomes the allowance position where the processing liquid L from the ejecting unit 21 falls to the substrate W. Then, as illustrated in FIG. 9B, when the ejecting unit 21 located above the container 31 is at a position deviated from the through hole 31d, it becomes the block position where the falling of the processing liquid L to the substrate W is blocked.

Therefore, as illustrated in FIG. 9B, when the container 31 is at the block position, the height of the ejection position of the ejecting unit 21 is set to be lower than the upper edge of the container 31, and when it is required to be at the allowance position, the ejecting unit 21 may be moved by a relatively short distance in the horizontal direction. As a result, when the container 31 is at the block position, the processing liquid L ejected from the ejecting unit 21 is prevented from being repelled from the container 31 and falling to the substrate W. The ejecting unit 21 at the allowance position may be inserted into the through hole 31d or may face the through hole 31d from above.

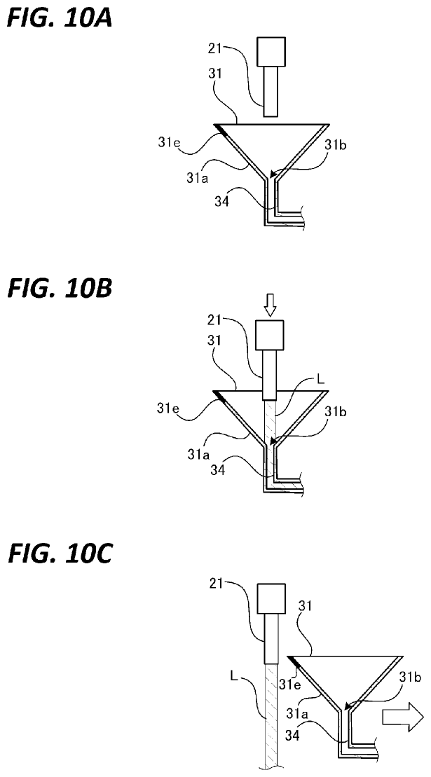

(5) As illustrated in FIG. 10A, when the container 31 is moved between the block position and the allowance position, a groove 31e (the portion painted black in the drawing) through which the ejecting unit 21 passes may be formed in the upper edge of the container 31 passing a lower side of the ejecting unit 21. Therefore, as illustrated in FIG. 10B, when the container 31 is at the block position, the height of the ejection position of the ejecting unit 21 is set to be lower than the upper edge of the container 31, and as illustrated in FIG. 10C, when it is required to be at the allowance position, the ejecting unit 21 may pass through the groove 31e. As a result, when the container 31 is at the block position, the processing liquid L ejected from the ejecting unit 21 is prevented from being repelled from the container 31 and falling to the substrate W.

(6) When the container 31 and ejecting unit 21 are displaced between the block position and the allowance position, both of them may be relatively moved. That is, the container 31 may be moved, the ejecting unit 21 may be moved, or both of the container 31 and the ejecting unit 21 may be moved.

(7) When performing the dummy ejection at the block position, the ejection position of the ejecting unit 21 may not be an upper side of the center of the substrate W.

(8) The shape of the container 31 is not limited to an inverted conical shape. Any shape may be used as long as the container 31 has an effect of blocking the processing liquid L. For example, the shapes illustrated in FIG. 4B and FIG. 4C described above are modifications of the embodiment that can block the processing liquid L.

(9) With regard to the supply nozzle of the various processing liquids illustrated in the above such as the DIW or the like, it is possible to switch between the dummy ejection and the main ejection in a relatively short time by using the receiving unit 30 described above. Further, a mechanism that supplies the liquid to the lower surface may be provided. For example, an ejecting unit may be provided to supply DIW to the lower surface to protect from the etching liquid that drips from the upper surface.

(10) The substrate W, which is a processing target, in the present embodiment is not limited to a semiconductor wafer, but may be various targets such as various display substrates. The type of the processing liquid is not limited to those illustrated in the above, and may be appropriately changed according to the processing target and the processing content.

From the foregoing, it will be appreciated that various embodiments of the present disclosure have been described herein for purposes of illustration, and that various Modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate processing apparatus comprising:
a rotator configured to hold and rotate a substrate;
a processing liquid supply including an ejector configured to supply a processing liquid from the ejector to a target surface of the substrate that is being rotated by the rotator, thereby processing the substrate; and
a receiver including a container having an open top, and provided to be relatively movable with respect to the ejector between a block position where the container blocks a supply of the processing liquid from the ejector to the substrate and an allowance position where the container allows the supply of the processing liquid from the ejector to the substrate.

2. The substrate processing apparatus according to claim 1, further comprising:
a shield provided to be movable in a direction of contacting with and being separated from the rotator, and facing the substrate in a non-contact manner,
wherein the shield is provided with a gas supply configured to supply a gas between a surface facing the substrate and the substrate.

3. The substrate processing apparatus according to claim 2, wherein the ejector is provided in the shield.

4. The substrate processing apparatus according to claim 1, wherein the ejector is provided to be movable between an ejection position where the processing liquid is ejected to the target surface of the substrate and a standby position that is deviated from an upper side of the target surface of the substrate, and
the container is provided to be movable from the ejection position to the standby position while maintaining the block position.

5. The substrate processing apparatus according to claim 4, wherein the container is provided to be movable to the ejection position together with the ejector while maintaining the block position.

6. The substrate processing apparatus according to claim 1, wherein, when the container is relatively moved from the block position to the allowance position, an outer surface of the container that passes a lower side of the ejector is inclined.

7. The substrate processing apparatus according to claim 2, wherein, when the container is relatively moved from the block position to the allowance position, an outer surface of the container that passes a lower side of the ejector is inclined.

8. The substrate processing apparatus according to claim 1, wherein, when the container is relatively moved from the block position to the allowance position, an outer surface of the container that passes a lower side of the ejector includes a sub-receiver that prevents the processing liquid flowing on the outer surface of the container from falling onto the target surface of the substrate.

9. The substrate processing apparatus according to claim 8, wherein an upper edge of the sub-receiver is positioned inward from an upper edge of the container.

10. The substrate processing apparatus according to claim 1, wherein a through hole facing the ejector is formed in the container.

11. The substrate processing apparatus according to claim 1, wherein a groove is formed in an upper edge of the container that passes a lower side of the ejector such that the ejector passes the groove when the container is relatively moved between the block position and the allowance position.

12. A substrate processing method comprising:
providing a substrate processing apparatus including:
a rotator configured to hold and rotate a substrate;
a processing liquid supply including an ejector configured to supply a processing liquid from the ejector to a target surface of the substrate that is being rotated by the rotator; and
a receiver including a container having an open top, and provided to be relatively movable with respect to the ejector between a block position where the container blocks a supply of the processing liquid from the ejector to the substrate and an allowance position where the container allows the supply of the processing liquid from the ejector to the substrate,
moving the container to the block position while the ejector ejects the processing liquid thereby blocking supply of the processing liquid to the substrate;
adjusting a flow rate and a temperature of the processing liquid ejected from the ejector while the processing liquid is being blocked; and
after adjusting the flow rate and the temperature of the processing liquid at the adjusting, relatively moving the container to the allowance position such that the processing liquid is supplied to a target surface of the substrate from the ejector thereby processing the substrate with the processing liquid.

13. The substrate processing method according to claim 12, wherein the flow rate and the temperature of the processing liquid are controlled by a flow rate controller and a temperature controller.
